(19) United States
(12) Patent Application Publication
(10) Pub. No.: US 2004/0079984 A1
(43) Pub. Date: Apr. 29, 2004

(54) Polysilicon self-aligned contact and a polysilicon common source line and method of forming the same

(76) Inventors: Hsuan-Ling Kao, Taipei (TW); Chun-Pei Wu, Nantou Hsien (TW); Hui-Huang Chen, Hsin-Chu (TW); Wen-Bin Tsai, Tainan (TW); Henry Chung, Hsin-Chu (TW)

Correspondence Address: BIRCH STEWART KOLASCH & BIRCH, PO BOX 747, FALLS CHURCH, VA, 22040-0747, US

(21) Appl. No.: 10/279,916

(22) Filed: Oct. 25, 2002

(51) Int. Cl. H01L 29/788

(52) U.S. Cl. 257/315

(57) ABSTRACT

A polysilicon self-alignment contact and a polysilicon common source line. A cell array formed on a semiconductor substrate has a second cell adjacent to a first cell in a Y-axis orientation, and a third cell adjacent to the first cell in an X-axis orientation. Each cell comprises a first gate structure and a second gate structure, a source region formed in the semiconductor substrate adjacent to the first gate structure and the second gate structure, and an opening formed between the first gate structure and the second gate structure to expose the source region. A drain region is formed in the semiconductor substrate adjacent to the second gate structure of the first cell and the first gate structure of the second cell. A contact hole is formed between the first cell and the second cell to expose the drain region. A polysilicon layer is formed in the contact hole to serve as a polysilicon self-aligned contact. Also, the polysilicon layer is formed in the opening to electrically connect source regions in an X-axis orientation to serve as a common source line.

### BACKGROUND OF THE INVENTION

1. Field of the Invention

The present invention relates to a self-aligned contact process and, more particularly, to a polysilicon self-alignment contact over a drain region and a polysilicon common source line over source regions and STI regions.

2. Description of the Related Art

In semiconductor device fabrication, e.g., memory devices (such as Mask ROM, Flash and EPROM) and logic devices (such as Micro Processor, Controller and CMOS Sensor), a self-aligned contact process enables gate structures to be placed closer together and reduce cell size without risk of shorts between the gate structure and the contact plug that is connected to a drain region. Also, a common source line is required to interconnect source regions of cells in wordline direction.

U.S. Pat. No. 6,194,784 discloses a self-aligned contact process to eliminate the contact-to-gate spacing. FIGS. 5A to 5C are sectional diagrams along bitline direction to show the self-aligned contact process. As shown in FIG. 5A, source regions 41 and drain regions 42 are formed in a semiconductor substrate 40, and gate structures 44 are patterned on the semiconductor substrate 40. Each gate structure 44 comprises a gate oxide layer 45, a floating gate layer 46, a dielectric layer 47, a control gate layer 48, and a tungsten silicide layer 49. Also, each gate structure 44 is encapsulated in an insulating layer 50 and an etch-stop layer 51. In the self-aligned contact process, a dielectric layer 52 is deposited to cover the entire surface of the semiconductor substrate 40, and then a photoresist layer 54 with an opening 55 is patterned on the dielectric layer 52. Next, as shown in FIG. 5B, using photolithography and dry etching, a contact hole 56 is formed to expose the drain region 42. Then, the photoresist layer 54 is removed. Thereafter, as shown in FIG. 5C, a conductive layer 58 is deposited to fill the contact hole 56, serving as a self-aligned contact plug. However, deposition, photolithography and etching must be employed to define the contact hole 56 in the dielectric layer 52, resulting in a smaller contact photo window and an increase in process costs.

U.S. Pat. No. 6,294,431 discloses a method of introducing dopants to form a common source line buried under field oxide zones. FIG. 6A is a top view showing the common source line process, and FIG. 6B is a sectional diagram along line IV-IV shown in FIG. 6A. On a silicon wafer 60, strips of active areas 64 are perpendicularly intersected by polysilicon strips 62 and isolated by field oxide zones 66. Also, source lines and regions 68 are defined between polysilicon strips 62. Using self-aligned source (SAS) process, a resist mask 70 is patterned to cover drain regions and is aligned to the middle of the polysilicon strips 62. Then, using ion implantation, dopants introduced into the silicon wafer 60 can pass through the field oxide zones 66 to form a buried silicon layer 72 with a high concentration of dopant. Next, through further implantation, source regions 74 are formed inside the strips of active areas 64 and electrically connected to the buried silicon layer 72. Thus, the buried silicon layer 72 under the field oxide zones 66 serves a common source line. However, this cannot ensure electric continuity in the common source line. Moreover, U.S. Pat. No. 6,218,265 discloses a method of using SAS with tilted implantation to form a common source line in a silicon substrate. However, this method encounters problems during etching and tilted implantation in a cavity.

### SUMMARY OF THE INVENTION

The present invention provides a polysilicon self-alignment contact over a drain region and a polysilicon common source line over source regions and STI regions to solve the above-described problems.

The present invention provides a polysilicon self-alignment contact and a polysilicon common source line for applications of memory devices (such as Mask ROM, Flash and EPROM) and logic devices (such as Micro Processor, Controller and CMOS Sensor). A semiconductor device has a cell array formed on a semiconductor substrate, in which a second cell is adjacent to a first cell in a Y-axis orientation, and a third cell is adjacent to the first cell in an X-axis orientation. Each cell comprises a first gate structure and a second gate structure patterned on the semiconductor substrate, a sidewall spacer formed on the sidewalls of the first gate structure and the second gate structure, a source region formed in the semiconductor substrate adjacent to the first gate structure and the second gate structure, and an opening formed between the first gate structure and the second gate structure to expose the source region. A drain region is formed in the semiconductor substrate adjacent to the second gate structure of the first cell and the first gate structure of the second cell. A contact hole is formed between the first cell and the second cell to expose the drain region. Using deposition, etching or photolithography, a polysilicon layer is formed in the contact hole to serve as a polysilicon self-aligned contact. Also, the polysilicon layer is formed in the opening to electrically connect source regions in an X-axis orientation to serve as a common source line.

Accordingly, it is a principal object of the invention to provide the polysilicon self-aligned contact without performing deposition, photolithography and etching on a dielectric layer.

It is another object of the invention to provide the polysilicon self-aligned contact to enlarge the contact photo window.

Yet another object of the invention is to provide the polysilicon common source line on the source regions and shallow trench isolations without encountering problems in extra etching and tilted implantation in a cavity.

It is a further object of the invention to provide the polysilicon common source line to simplify process and ensure electrical properties.

These and other objects of the present invention will become readily apparent upon further review of the following specification and drawings.

### BRIEF DESCRIPTION OF THE DRAWINGS

FIG. 1 is a top view showing a layout of a memory device according to the first embodiment of the present invention;

FIGS. 2A and 2B are sectional diagrams along line I-I in FIG. 1 to show a method of forming a polysilicon self-alignment contact;

FIG. 2C is a sectional diagram along line II-II in FIG. 1 showing the drain regions in an X-axis orientation;

FIG. 2D is a sectional diagram along line III-III in FIG. 1 showing a common source line;

FIG. 3 is a top view showing a layout of a memory device according to the second embodiment of the present invention;

FIG. 4A is a sectional diagram along line I-I in FIG. 3 showing a polysilicon self-alignment contact;

FIG. 4B is a sectional diagram along line II-II in FIG. 3 showing the drain regions in an X-axis orientation;

FIG. 4C is a sectional diagram along line III-III in FIG. 3 showing a common source line;

FIGS. 5A to 5C are sectional diagrams along bitline direction to show the self-aligned contact process;

FIG. 6A is a top view showing the common source line process; and

FIG. 6B is a sectional diagram along line IV-IV shown in FIG. 6A.

Similar reference characters denote corresponding features consistently throughout the attached drawings.

### DETAILED DESCRIPTION OF THE PREFERRED EMBODIMENTS

The present invention provides a polysilicon self-alignment contacting a polysilicon common source line for applications of memory devices, e.g., Mask ROM, Flash and EPROM and logic devices, e.g., Micro Processor, Controller and CMOS Sensor.

### First Embodiment

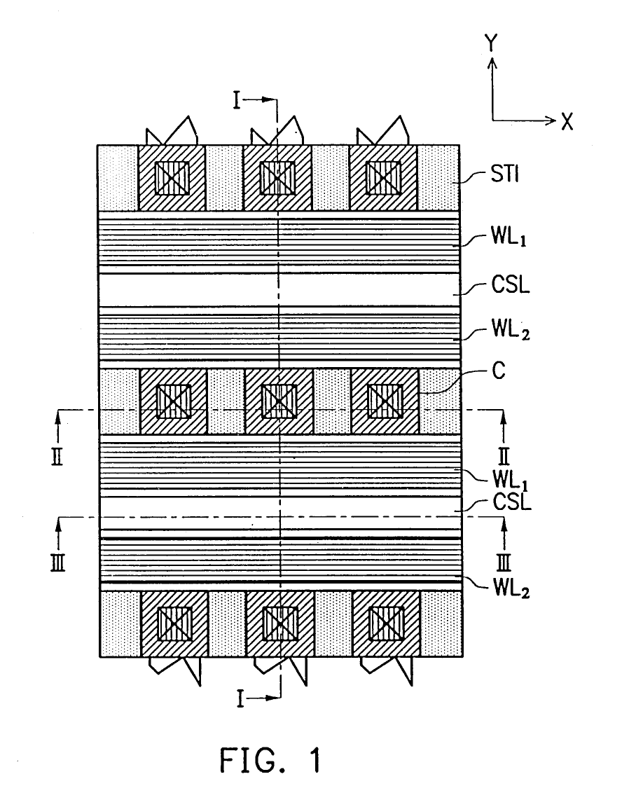

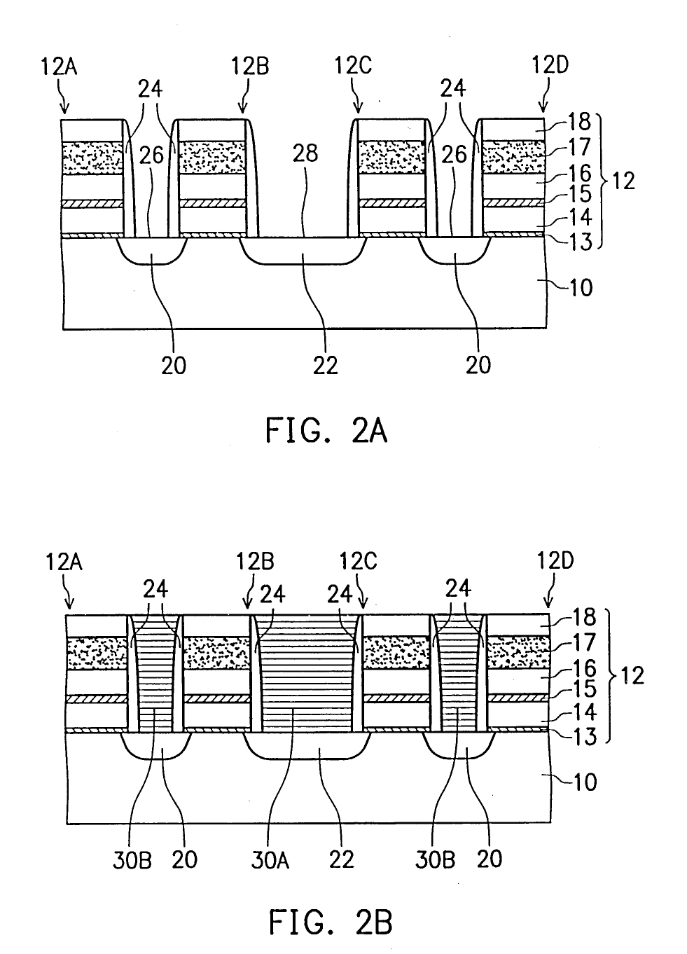

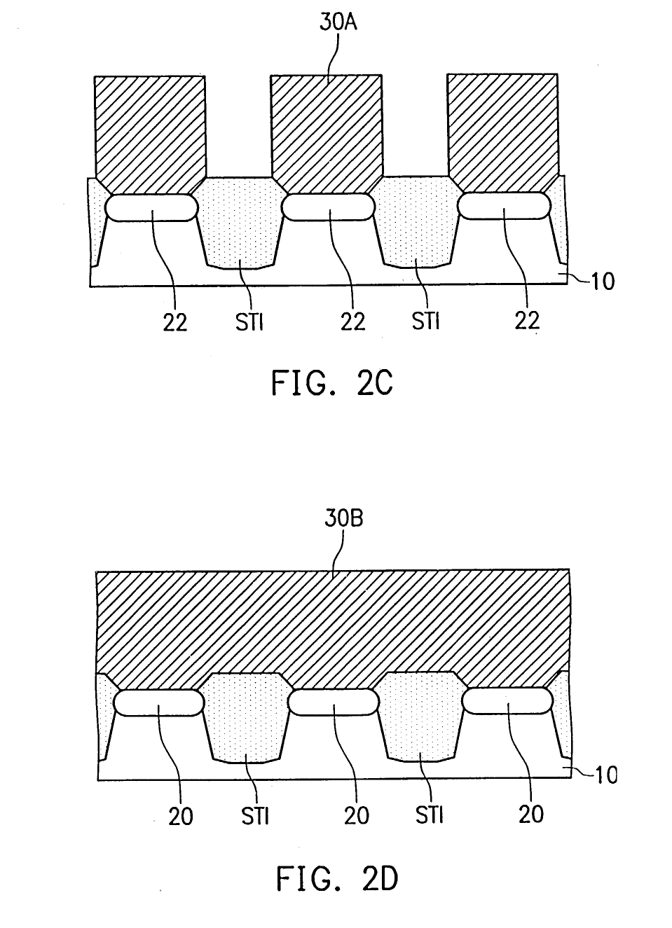

FIG. 1 is a top view showing a layout of a memory device according to the first embodiment of the present invention. FIGS. 2A and 2B are sectional diagrams along line I-I in FIG. 1 to show a method of forming a polysilicon self-alignment contact. FIG. 2C is a sectional diagram along line II-II in FIG. 1 showing the drain regions in an X-axis orientation. FIG. 2D is a sectional diagram along line III-III in FIG. 1 showing a common source line.

Referring to FIG. 1, for a FLASH EPROM device, the memory cell array is defined by shallow trench isolation regions (STI). Each memory cell comprises a first wordline (WL₁) extending in an X-axis orientation, a second wordline (WL₂) extending in an X-axis orientation and a bitline extending in a Y-axis orientation, in which a common source line (CSL) extending in an X-axis orientation is formed between the first wordline and the second wordline to electrically connect source regions. Also, a polysilicon self-aligned contact (C) is formed over a drain region commonly used by two adjacent memory cells in a Y-axis orientation.

As shown in FIG. 2A, in a Y-axis orientation, pairs of stacked gate structures 12A, 12B, 12C and 12D, serving as wordline structures, are patterned on a semiconductor substrate 10. Each stacked gate structure 12 comprises a gate oxide layer 13, a floating gate layer 14, an ONO tri-layer 15, a control gate layer 16, a tungsten silicide layer 17 and a nitride cap layer 18. A source region 20 formed by introducing dopants into the semiconductor substrate 10 is adjacent to stacked gate structures 12A and 12B. Also, the source region 20 is formed in the semiconductor substrate 10 adjacent to stacked gate structures 12C and 12D. A drain region 22 formed by introducing dopants in the semiconductor substrate 10 is adjacent to stacked gate structures 12B and 12C. Further, a sidewall spacer 24 of oxide or nitride is formed on the sidewall of the stacked gate structure 12 by dielectric deposition and anisotropic etching. Moreover, an opening 26 is formed to expose the source region 20, and a contact hole 28 is formed between the two stacked gate structures 12B and 12C to expose the drain region 22.

To form a polysilicon self-aligned contact, as shown in FIG. 2B, a polysilicon layer 30 is deposited on the entire surface of the semiconductor substrate 10 reaching a predetermined thickness to fill the opening 26 and the contact hole 28. Then, using etching or CMP, the polysilicon layer 30 is etched back and leveled off with the top of the nitride cap layer 18. Thus, the polysilicon layer 30 remaining in the contact hole 28 serves as a polysilicon self-alignment contact 30A. Also, the polysilicon layer 30 remaining in the opening 26 electrically connects the source regions 20 along the wordline direction to serve as a common source line 30B.

As shown in FIG. 2C, in an X-axis orientation over the drain regions 22, the polysilicon self-alignment contact 30A is patterned on the drain region 22 to expose the shallow trench isolation regions (STI). As shown in FIG. 2D, in an X-axis orientation over the source regions 20, the strip of the common source line 30B is formed on the shallow trench isolation regions (STI) and the source regions 20.

Compared with the prior art, the present invention provides the polysilicon self-aligned contact 30A in the contact hole 28 without performing deposition, photolithography and etching on a dielectric layer to define a polysilicon contact. This increases the contact photo window. Also, compared with the prior art of using SAS techniques or STI process with tilted implantation to form a common source line, the present invention provides the polysilicon common source line 30B on the source regions 20 and shallow trench isolations (STI) in an X-axis orientation without encountering problems in extra etching and tilted implantation in a cavity. This simplifies the process and ensures electrical properties.

### Second Embodiment

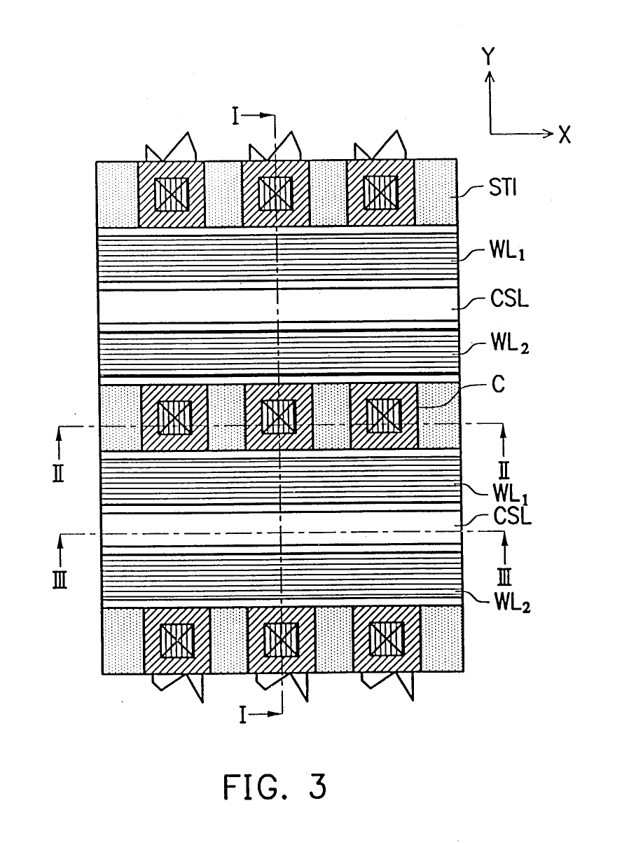

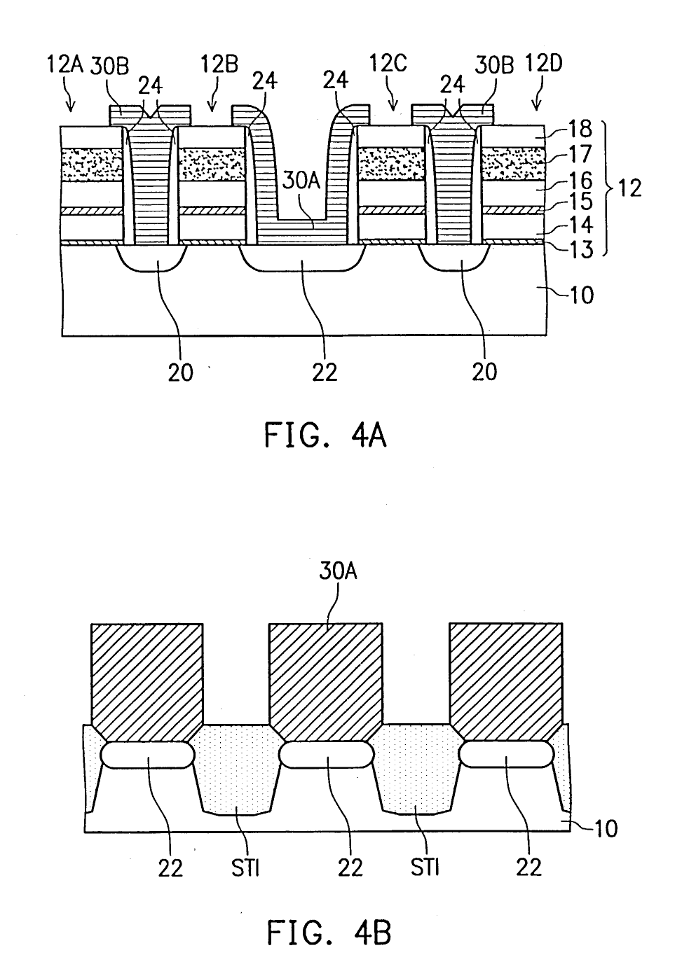

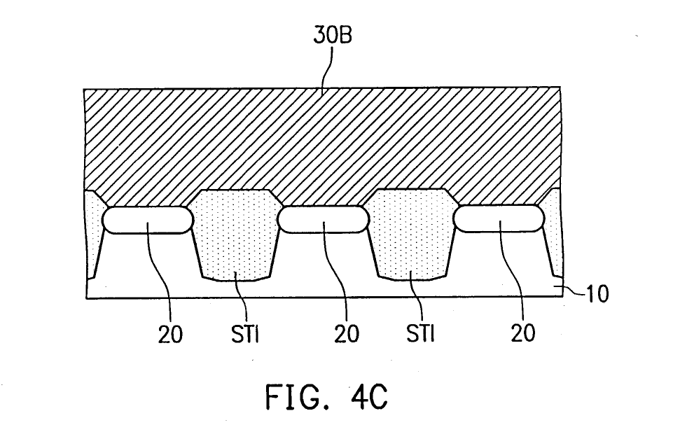

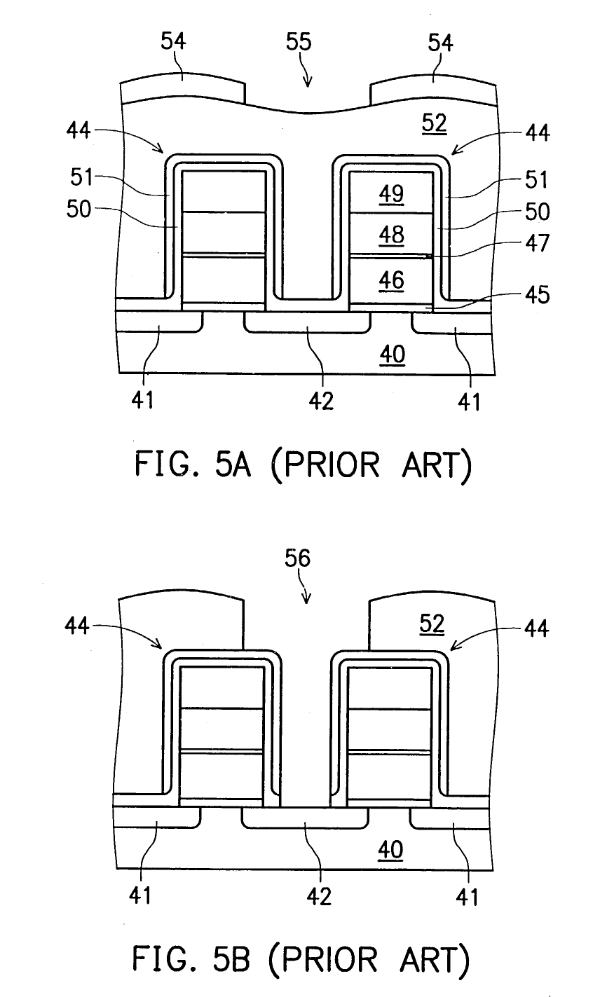

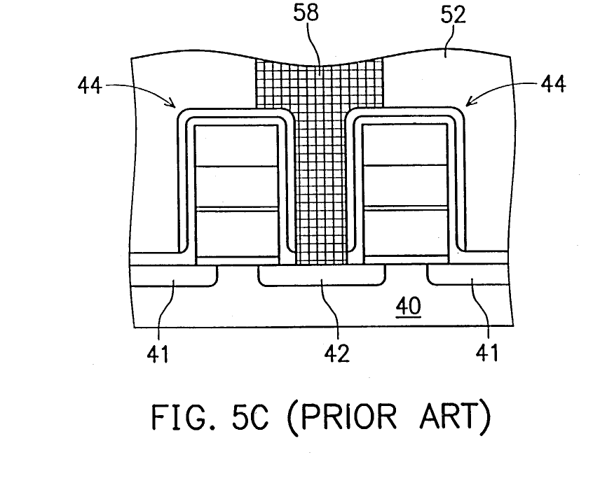

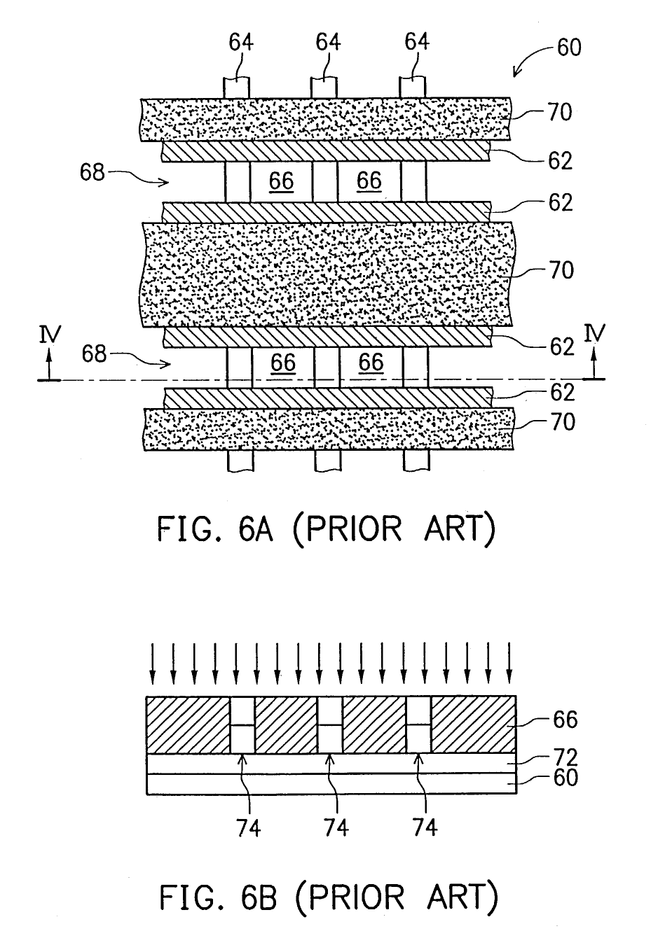

FIG. 3 is a top view showing a layout of a memory device according to the second embodiment of the present invention. FIG. 4A is a sectional diagram along line I-I in FIG. 3 showing a polysilicon self-alignment contact. FIG. 4B is a sectional diagram along line II-II in FIG. 3 showing the drain regions in an X-axis orientation. FIG. 4C is a sectional diagram along line III-III in FIG. 3 showing a common source line.

Referring to FIG. 3, for a FLASH EPROM device, the memory cell array is defined by shallow trench isolation regions (STI). Each memory cell comprises a first wordline (WL₁) extending in an X-axis orientation, a second wordline (WL₂) extending in an X-axis orientation and a bitline extending in a Y-axis orientation, in which a common source line (CSL) extending in an X-axis orientation is formed between the first wordline and the second wordline to electrically connect source regions. Also, a polysilicon self-aligned contact (C) is formed over a drain region common used by adjacent memory cells in a Y-axis orientation.

Referring to FIG. 4A, to form a polysilicon self-aligned contact in the same semiconductor substrate 10 shown in FIG. 2A, a polysilicon layer 30 is deposited on the entire surface of the semiconductor substrate 10 to fill the opening 26 without completely filling the contact hole 28. It is noted that the thinner polysilicon layer 30 is just deposited on the sidewall and bottom of the contact hole 28. Then, using photolithography and etching, the polysilicon layer 30 is patterned and separated as the polysilicon self-alignment contact 30A and the polysilicon common source line 30B. As shown in FIG. 4B, in an X-axis orientation over the drain regions 22, the polysilicon self-alignment contact 30A is patterned on the drain region 22 to expose the shallow trench isolation regions (STI). As shown in FIG. 4C, in an X-axis orientation over the source regions 20, the strip of the polysilicon common source line 30B is formed on the shallow trench isolation regions (STI).

It is to be understood that the present invention is not limited to the embodiments described above, but encompasses any and all embodiments within the scope of the following claims.

What is claimed is:

1. A polysilicon self-aligned contact and a polysilicon common source line, comprising:
a first cell, which comprises a first gate structure and a second gate structure on a semiconductor substrate, a sidewall spacer on the sidewalls of the first gate structure and the second gate structure, a source region in the semiconductor substrate adjacent to the first gate structure and the second gate structure, and an opening between the first gate structure and the second gate structure to expose the source region;
a second cell which is adjacent to the first cell in a Y-axis orientation and comprises a first gate structure and a second gate structure on the semiconductor substrate, a sidewall spacer on the sidewalls of the first gate structure and the second gate structure, a source region in the semiconductor substrate adjacent to the first gate structure and the second gate structure, and an opening between the first gate structure and the second gate structure to expose the source region;
a drain region in the semiconductor substrate adjacent to the second gate structure of the first cell and the first gate structure of the second cell;
a contact hole which is between the first cell and the second cell to expose the drain region;
a polysilicon self-aligned contact formed in the contact hole; and
a polysilicon common source line formed in the opening

2. The polysilicon self-aligned contact and a polysilicon common source line according to claim 1, wherein the polysilicon self-aligned contact completely fills the contact hole.

3. The polysilicon self-aligned contact and a polysilicon common source line according to claim 1, wherein the polysilicon self-aligned contact is formed on the sidewall and bottom of the contact hole.

4. The polysilicon self-aligned contact and a polysilicon common source line according to claim 1, further comprising:
a third cell adjacent to the first cell in an X-axis orientation; and
a shallow trench isolation region formed in the semiconductor substrate to isolate the source regions of the first cell and the third cell.

5. The polysilicon self-aligned contact and a polysilicon common source line according to claim 4, wherein the common source line is formed on the source regions and the shallow trench isolation in an X-axis orientation.

6. The polysilicon self-aligned contact and a polysilicon common source line according to claim 1, wherein the sidewall spacer is oxide or nitride.

7. The polysilicon self-aligned contact and a polysilicon common source line according to claim 1, wherein the semiconductor device is Mask ROM, Flash, EPROM, Micro Processor, Controller or CMOS Sensor.

8. The polysilicon self-aligned contact and a polysilicon common source line according to claim 1, wherein the gate structure is a stacked form comprising a gate oxide layer, a floating gate layer, an ONO layer, a control gate layer, and a cap layer.

9. The polysilicon self-aligned contact and a polysilicon common source line according to claim 8, wherein the gate structure further comprises a metal silicide layer disposed between the control gate layer and the cap layer.

10. A method of forming polysilicon self-aligned contact and a polysilicon common source line, comprising steps of:
providing a first cell and a second cell adjacent to the first cell in a Y-axis orientation, wherein each cell comprises a first gate structure and a second gate structure patterned on a semiconductor substrate, a sidewall spacer formed on the sidewalls of the first gate structure and the second gate structure, a source region formed in the semiconductor substrate adjacent to the first gate structure and the second gate structure, and an opening formed between the first gate structure and the second gate structure to expose the source region, a drain region formed in the semiconductor substrate adjacent to the second gate structure of the first cell and the first gate structure of the second cell, and a contact hole formed between the first cell and the second cell to expose the drain region;
depositing a polysilicon layer on the entire surface of the semiconductor substrate to fill the opening and the contact hole; and
using CMP to level off the surface of the polysilicon layer with the surface of the gate structures, wherein the polysilicon layer formed in the contact hole serves as a polysilicon self-aligned contact, and formed in the opening serves as a common source line.

11. The method of forming polysilicon self-aligned contact and a polysilicon common source line according to claim 10, wherein the semiconductor substrate further comprises:
a third cell adjacent to the first cell in an X-axis orientation; and
a shallow trench isolation region formed in the semiconductor substrate to isolate the source regions of the first cell and the third cell.

12. The method of forming polysilicon self-aligned contact and a polysilicon common source line according to claim 11, wherein the common source line is formed on the source regions and the shallow trench isolation in an X-axis orientation.

13. The method of forming polysilicon self-aligned contact and a polysilicon common source line according to claim 11, wherein the sidewall spacer is oxide or nitride.

14. The method of forming polysilicon self-aligned contact and a polysilicon common source line according to claim 10, wherein the semiconductor substrate is used to manufacture Mask ROM, Flash, EPROM, Micro Processor, Controller or CMOS Sensor.

15. The method of forming polysilicon self-aligned contact and a polysilicon common source line according to claim 10, wherein the gate structure is a stacked form comprising a gate oxide layer, a floating gate layer, an ONO layer, a control gate layer, and a cap layer.

16. A method of forming polysilicon self-aligned contact and a polysilicon common source line, comprising steps of:
providing a first cell and a second cell adjacent to the first cell in a Y-axis orientation, wherein each cell comprises a first gate structure and a second gate structure patterned on a semiconductor substrate, a sidewall spacer formed on the sidewalls of the first gate structure and the second gate structure, a source region formed in the semiconductor substrate adjacent to the first gate structure and the second gate structure, and an opening formed between the first gate structure and the second gate structure to expose the source region, a drain region formed in the semiconductor substrate adjacent to the second gate structure of the first cell and the first gate structure of the second cell, and a contact hole formed between the first cell and the second cell to expose the drain region;
depositing a polysilicon layer on the entire surface of the semiconductor substrate to fill the opening without completely filling the contact hole; and
patterning the polysilicon layer, wherein the polysilicon layer formed in the contact hole serves as a polysilicon self-aligned contact, and formed in the opening serves as a common source line.

17. The method of forming polysilicon self-aligned contact and a polysilicon common source line according to claim 16, wherein the semiconductor substrate further comprises:
a third cell adjacent to the first cell in an X-axis orientation; and
a shallow trench isolation region formed in the semiconductor substrate to isolate the source regions of the first cell and the third cell.

18. The method of forming polysilicon self-aligned contact and a polysilicon-common source line according to claim 17, wherein the common source line is formed on the source regions and the shallow trench isolation in an X-axis orientation.

19. The method of forming polysilicon self-aligned contact and a polysilicon common source line according to claim 17, wherein the sidewall spacer is oxide or nitride.

20. The method of forming polysilicon self-aligned contact and a polysilicon common source line according to claim 16, wherein the semiconductor substrate is used for manufacturing Mask ROM, Flash, EPROM, Micro Processor, Controller or CMOS Sensor.

21. The method of forming polysilicon self-aligned contact and a polysilicon common source line according to claim 16, wherein the gate structure is a stacked form comprising a gate oxide layer, a floating gate layer, an ONO layer, a control gate layer, and a cap layer.
